(19) United States
(12) Patent Application Publication
(10) Pub. No.: US 2015/0372180 A1
(43) Pub. Date: Dec. 24, 2015

(54) OXYGEN DOPED CADMIUM MAGNESIUM TELLURIDE ALLOY

(71) Applicants: Toyota Motor Engineering & Manufacturing North America, Inc., Erlanger, KY (US); The Regents of the University of Michigan, Ann Arbor, MI (US)

(72) Inventors: Li Qin Zhou, Ann Arbor, MI (US); Chen Ling, Ann Arbor, MI (US); Hongfei Jia, Ann Arbor, MI (US); Jamie Dean Phillips, Ann Arbor, MI (US); Chihyu Chen, Ann Arbor, MI (US)

(21) Appl. No.: 14/312,114

(22) Filed: Jun. 23, 2014

(51) Int. Cl. H01L 31/073; H01L 31/0725; C22C 20/00

(52) U.S. Cl. CPC H01L 31/073; C22C 20/00; H01L 31/0725

(57) ABSTRACT

A band gap material includes an alloy of cadmium, tellurium and magnesium. The alloy is doped with oxygen wherein the alloy includes an intermediate band positioned between conduction and valance bands of the alloy. The alloy has the formula: Cd₁₋ₓMgₓTeO_{y} wherein 0.1≦x≦0.75 and y≦0.1.

### FIELD OF THE INVENTION

The invention relates to band gap materials including an intermediate band for photonic applications.

### BACKGROUND OF THE INVENTION

In general, photovoltaic devices are based on semiconductor materials whose electronic structure contains a valence band and a conduction band that includes electrons or is void of electrons separated by a range of electron prohibited energies that define a band gap. In these materials, the absorption of a photon of electromagnetic radiation with energy the same as or higher than the width of the band gap transmits an electron from the conduction band to the valence band crossing the band gap. The electron may produce current and electric voltage converting light energy into electrical energy.

Various techniques have been considered in the prior art to increase the efficiency of the conversion of light energy into electrical energy. For example, multi-junction cells have been proposed that include stacks of solar cells made of semiconductors with different band gaps. The band gaps of the solar cells in the stack are chosen to maximize the efficiency of solar energy conversion. Typically prior art multi junction solar cells require numerous layers of materials and require a complex process to form them.

Semiconductors with intermediate band (IB) have recently attracted great attention as one of the most promising candidates to enhance the adsorption efficiency of solar radiation. Theoretically it is possible to go beyond the Shockley-Queisser efficiency limit with IB materials. The maximum theoretical light adsorption efficiency of IB material can reach 62% with the optimal valence band (VB) to conduction band (CB) band gap of around 1.93 eV and IB-CB band gap of approximate 0.7 eV.

In intermediate band gap materials in addition to the valence and conduction bands, there is another band that is energetically positioned between both, and which can be partially occupied by electrons. The intermediate band allows the absorption of two photons with energies lower than the band gap of the material or the difference between the valence and conduction bands. In other words, there is the possible transmission of an electron of the valence band to the intermediate band and the intermediate band to the conduction band thereby increasing the efficiency. There is therefore a need in the art for materials with a tailored electronic structure that increase the efficiency of photonic applications. There is also a need in the art for a band gap material that includes an intermediate band gap increasing the efficiency of photonic applications. There is also a need in the art for improved band gap materials that approach the optimal valence to conduction band gap.

### SUMMARY OF THE INVENTION

In one aspect, there is disclosed a band gap material that includes an alloy of cadmium, tellurium and magnesium. The alloy is doped with oxygen wherein the alloy includes an intermediate band positioned between conduction and valance bands of the alloy. The alloy has the formula: Cd₁₋ₓMgₓTeO_{y} wherein 0.1≦x≦0.75 and y≦0.1.

In another aspect, there is disclosed a band gap material that includes a GaAs substrate, a buffer layer of ZnTe applied to the GaAs substrate, and a buffer layer of CdTe applied to the buffer layer of ZnTe. An alloy is applied to the buffer layer of CdTe. The alloy being of cadmium, tellurium and magnesium. The alloy is doped with oxygen wherein the alloy includes an intermediate band positioned between conduction and valance bands of the alloy. The alloy has the formula: Cd₁₋ₓMgₓTeO_{y} wherein 0.1≦x≦0.75 and y≦0.1.

### BRIEF DESCRIPTION OF THE DRAWINGS

FIG. 1 is a plot of energy of Mg_{0.25}Cd_{0.75}Te per atom as a function of volume per atom;

FIG. 2 is a plot of the relative energy of oxygen in Mg_{0.25}Cd_{0.75}Te as a function of its local environment;

FIG. 3 is a plot of the percentage of oxygen at different local environments in Mg_{0.25}Cd_{0.75}Te;

FIG. 4 is a graphical depiction of a band gap material;

FIG. 5 provides XRD plots of (a) CdMgTe and (b) CdMgTeO films;

FIG. 6 provides SIMS oxygen depth profiles of (a) CdMgTe and (b) CdMgTeO films;

FIG. 7 provides PL spectra of CdMgTe and CdMgTeO films;

FIG. 8 is a plot of the Band gap of CdMgTe as a function of Mg content;

FIG. 9 provides SIMS depth profiles of Mg, Cd and Te for (a) CdMgTe and (b) CdMgTeO films; and

FIG. 10 is a plot of the estimated PL laser absorption.

### DETAILED DESCRIPTION OF THE PREFERRED EMBODIMENTS

In one aspect, there is disclosed a band gap material that includes an alloy of cadmium, tellurium and magnesium. The alloy is doped with oxygen wherein the alloy includes an intermediate band positioned between conduction and valance bands of the alloy. The alloy has the formula: Cd₁₋ₓMgₓTeO_{y} wherein 0.1≦x≦0.75 and y≦0.1. The band gap material may have a band gap of from 2.5 to 1.6 eV. Various band gaps may be achieved by manipulation of the ratio of Mg/Cd in the material.

In one aspect the band gap material may have the formula Mg_{0.25}Cd_{0.75}TeO and have a band gap of 1.9 eV between conduction and valance bands of the material.

In another aspect, there is disclosed a band gap material that includes a GaAs substrate, a buffer layer of ZnTe applied to the GaAs substrate; and a buffer layer of CdTe applied to the buffer layer of ZnTe. An alloy is applied to the buffer layer of CdTe. The alloy being of cadmium, tellurium and magnesium. The alloy is doped with oxygen wherein the alloy includes an intermediate band positioned between conduction and valance bands of the alloy. The alloy has the formula: Cd₁₋ₓMgₓTeO_{y} wherein 0.1≦x≦0.75 and y≦0.1.

Density Functional Theory (DFT) calculations were performed with the Vienna ab initio Simulation Package (VASP) using projector augmented waves (PAW) pseudopotentials for the generalized gradient approximation (GGA). Numerical convergence to less than 2 meV per CoWO4 unit was ensured by using cutoff energy 400.0 eV and Monkhorst k-point mesh with the density of at least 0.03 Å-1.

Mg_{0.25}Cd_{0.75}Te alloy has a zinc blende structure, with Te occupying the anion site and Mg/Cd randomly occupying cation site. To model this random alloy, we apply the special quasi-random alloy (SQSA) model. In the zinc blende structure, anions are surrounded by four cations in a tetrahedral arrangement. The stability of oxygen may be related to the number of Mg (Cd) ions.

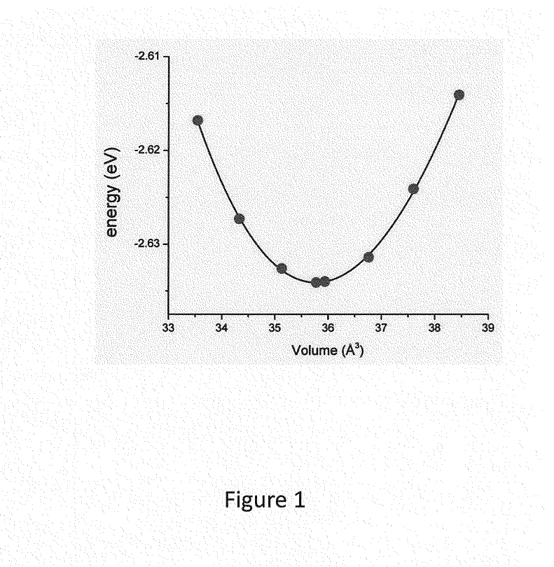

Referring to FIG. 1, there is shown the total energy of Mg_{0.25}Cd_{0.75}Te SQSA as a function of lattice parameter. The energy was determined as a function of volume using Murnagham's Equation of State as

$$E ( V ) = {B}_{0} {V}_{0} [ \frac{{V}_{0}^{{B}_{1} - 1}}{{B}_{1} ( {B}_{1} - 1 ) {V }^{{B}_{1} - 1}} + \frac{V}{{B}_{1} {V}_{0}} - \frac{1}{{B}_{1} - 1} ] + {E}_{0}$$

where B₀ is the bulk modulus, B₁ the first derivative of the bulk modulus, E₀ the energy at zero pressure, and V₀ the volume at zero pressure. The lattice constant of Mg_{0.25}Cd_{0.75}Te is determined to be 6.590 Å, while its bulk modulus is 35.95 GPa. The parameters in the equation were determined to be as follows: E₀ (eV)=−2.6341, V₀ (Å³)=35.7695, B₀ (GPa)=35.95 and B1=3.747.

In Mg_{0.25}Cd_{0.75}Te, the doped oxygen may be located at the anion site and may be surrounded by cations. If we only consider the randomness of cations nearest to oxygen, there are five configurations: Mg₄, Mg₃Cd, Mg₂Cd₂, MgCd₃ and Cd₄.

The probabilities of the configurations are determined by the percentage of Mg and Cd in the alloy. Because Mg may be present in an amount that represents a minority of cation, most substitution sites may be Mg-poor (Mg₂Cd₂, MgCd₃ and Cd₄). Only about five percent of substitution sites are Mg-rich (Mg₄ and Mg₃Cd) in this alloy.

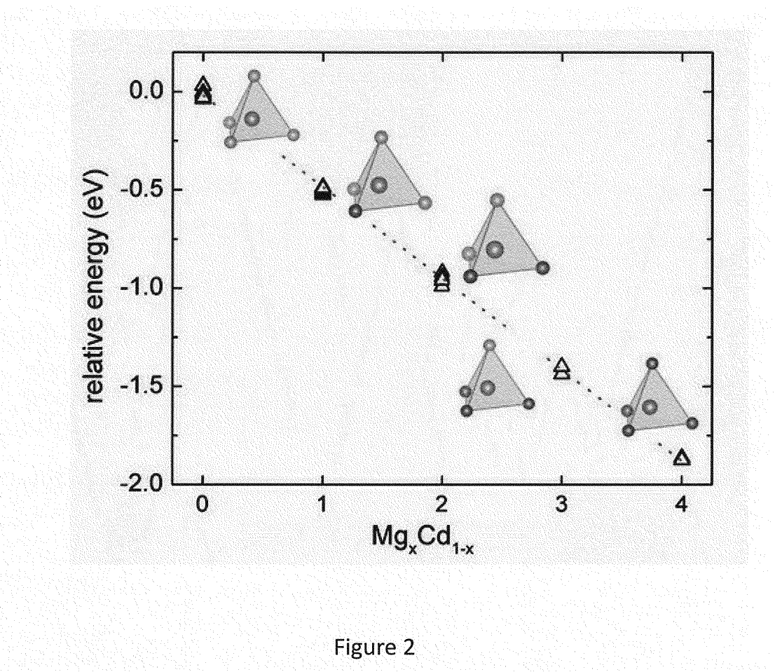

DFT calculations were carried out to obtain the energy of oxygen substitution at different local environments. A plot of the DFT calculations is shown in FIG. 2. As can be seen from the plot, the energy of oxygen may be determined by the number nearest Mg (Cd). Further, the energy linearly decreases with the number of nearest Mg. This trend can be interpreted as oxygen tends to bind with Mg rather than Cd. The fitted slope is −0.497 eV per Mg.

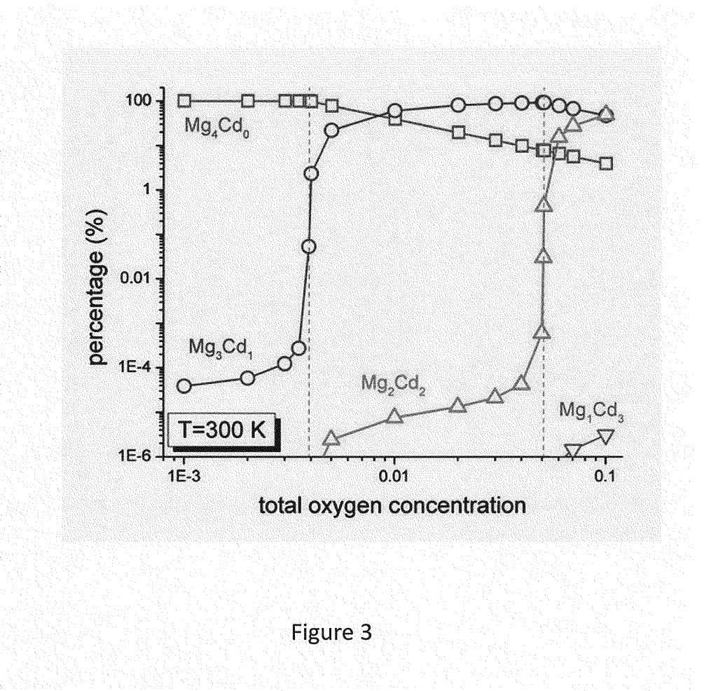

Referring to FIG. 3, there is shown the percentage of oxygen at different local environments in Mg_{0.25}Cd_{0.75}Te. As shown by the plot, oxygen prefers a Mg-rich site. For a total oxygen concentration less than 0.4%, more than 99.9% of the oxygen is located at the Mg₄ site. For a doping level above 0.4%, nearly all the Mg₄ sites are occupied and oxygen starts to occupy the Mg₃Cd₁ site. The occupation of Mg₂Cd₂ site only begins after the total oxygen concentration exceeds 5%. This characteristic is a result of the strong Mg—O bonding and demonstrates that oxygen prefers to occupy an Mg-rich site as opposed to a random distribution in the anion lattice.

The DFT simulations demonstrate that doping oxygen into MgTe can form an IB in the band structure, while only band gap narrowing can be seen in CdTeO. For the CdMgTe alloy, oxygen favors to locate at the Mg rich site. As a result CdMgTeO exhibits MgTeO-like characteristics. An intermediate band gap (IB) will form in alloys even with low Mg concentrations.

### EXAMPLES

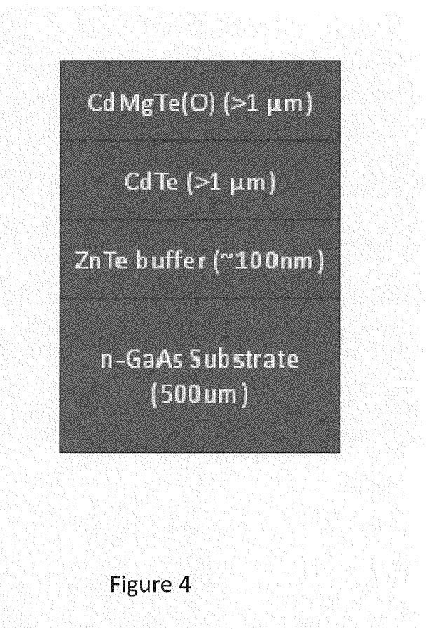

CdMgTe and CdMgTeO thin films were grown on GaAs(100) substrates by MBE. The buffer layers were applied to the GaAs substrates to enhance the epitaxial growth. A layer of approximately 100 nm ZnTe was applied to the GaAs substrate and a layer less than 1 μm of CdTe buffer was applied to the ZnTe layer prior to CdMgTe/CdMgTeO growth. A graphical representation of the band gap material is shown in FIG. 4.

Analytical tests were performed on the samples including X-ray diffraction analysis performed using a Rigaku Smartlab X-ray diffractometer with Cu Kα radiation (λ=1.5405 Å), PL measurements were performed with a HeCd laser operating at 325 nm, monochrometer, and closed cycle helium cryostat. SIMS analysis was also performed.

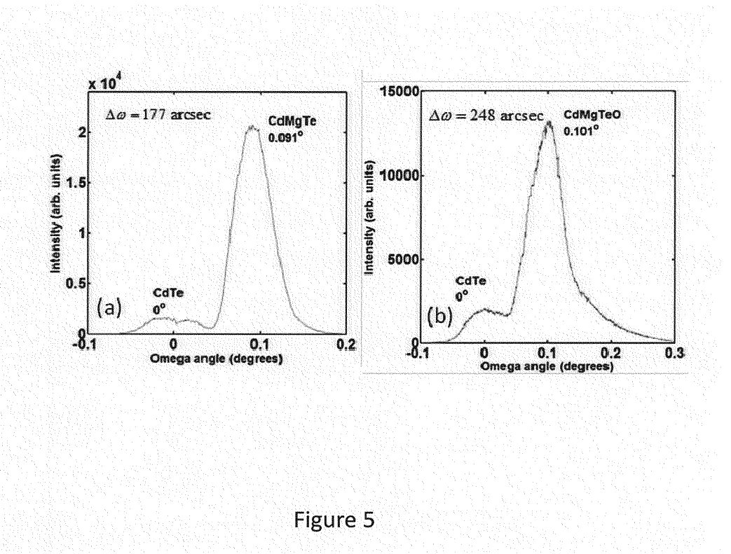

Referring to FIG. 5, the reflection curves of CdMgTe and CdMgTeO films are shown in Figure (a) and (b). CdTe and CdMgTe/CdMgTeO peaks are observed in the figures indicating a successful alloying of Mg into CdTe. Both films showed small full width at half maximum (FWHM) indicating that high quality epitaxial films were formed.

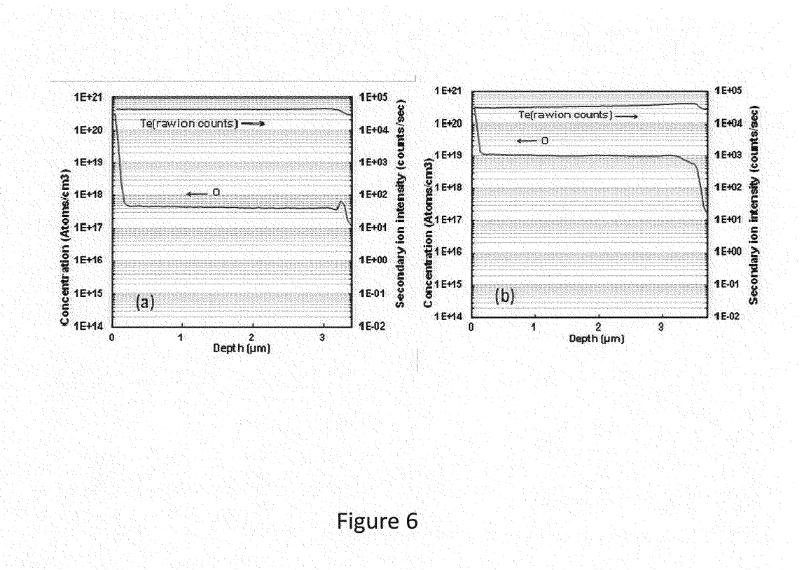

Referring to FIG. 6, there are shown SIMS depth profiles verifying the incorporation of oxygen into the films. Oxygen was detected in the CdMgTeO sample (FIG. 6b). Oxygen was also detected in the CdMgTe film (FIG. 6a) but at a lower concentration. The profile as shown in FIG. 6b indicates that the O concentration was uniform throughout the CdMgTeO film.

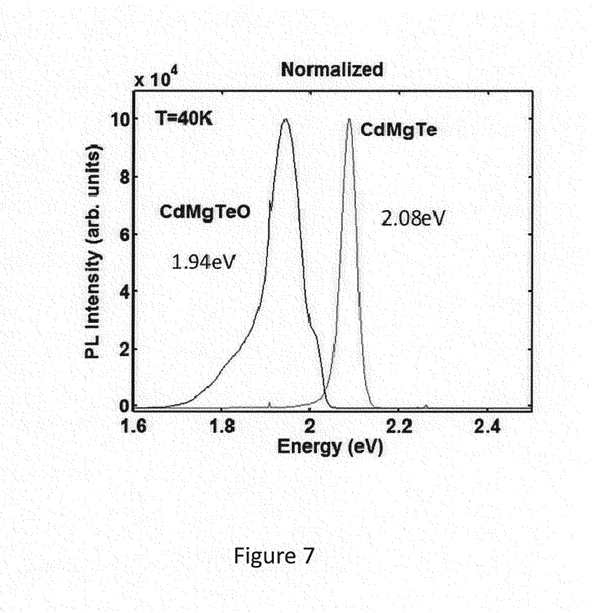

Referring to FIG. 7, there is shown plots of the PL spectra for both CdMgTe and CdMgTeO samples. A clear band gap reduction was seen for the CdMgTeO sample (1.94 eV) in comparison to the CdMgTe film (2.08 eV). Additionally, as shown in FIG. 7, a shoulder is shown in the plot around 1.8 eV in the PL spectra of oxygen doped CdMgTeO. The shoulder indicates the presence of an intermediate band gap (TB).

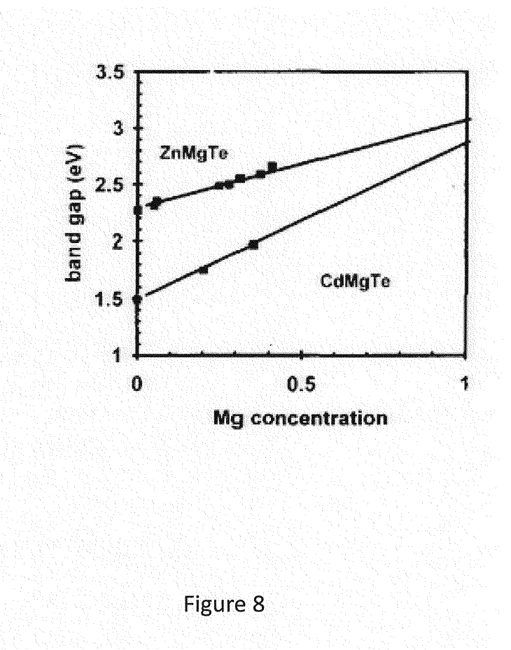

As discussed above, the Mg composition in the CdMgTe alloy (Mg/(Cd+Mg)) shifts the band gap of the alloy with a theoretical shift rate of 2 eV/Mg. Referring to FIG. 8, there is shown a plot of the band gap as a function of the Mg concentration. As can be seen in the plot, the experimental shift rate is about 1.25 eV/Mg.

Secondary ion mass spectrometry (SIMS) analysis was performed on Mg, Cd and Te compositions to analyze the band gap reduction of the CdMgTeO material. The MgCdTe composition was quantified using SIMS data by assuming the average Mg concentration was 0.3 in the CdMgTe sample.

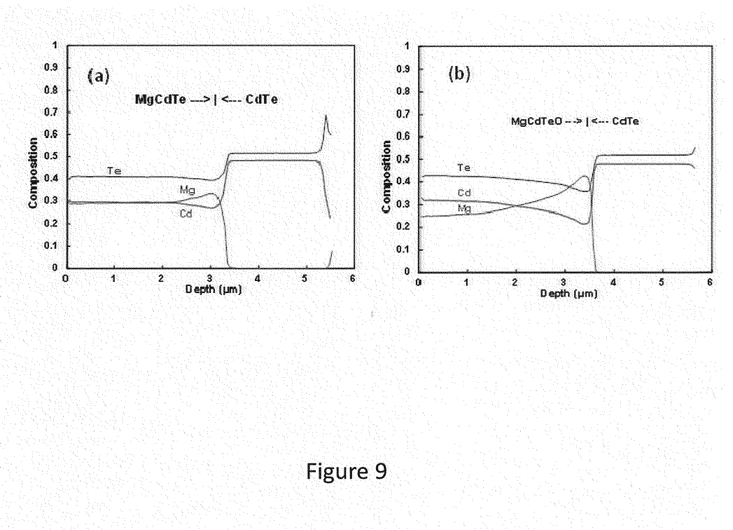

Referring to FIG. 9, there is shown the depth profiles of Mg, Cd and Te compositions for CdMgTe and CdMgTeO. As can be seen in the plots, the Mg composition near the film surface for the CdMgTeO sample (FIG. 9b) was less than that near the CdMgTe film surface (FIG. 9a). The absorption coefficient of MgCdTe was selected to be similar to CdTe and have a value of 8×10⁴ cm⁻¹.

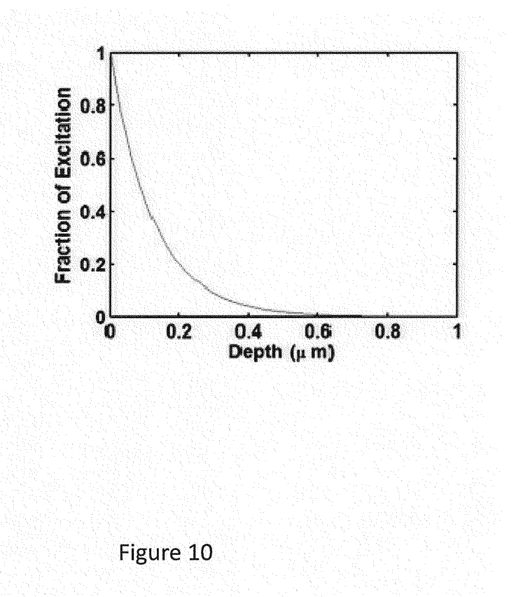

The absorption depth of the PL laser was then calculated to be less than 1 μm, as shown in FIG. 10. Again referring to FIG. 7, the PL spectra should be sensitive to Mg composition near the surface less than 1 μm. Using the band gap shift rate of 1.25 eV/Mg as shown in FIG. 8 in combination with a 10% change in Mg composition as shown in FIG. 9 for the CdMgTeO and CdMgTe samples resulted in a band gap reduction of 0.125 eV. This band gap reduction is verified in the PL spectra of FIG. 7.

The oxygen doped cadmium magnesium telluride band gap materials may be utilized in solar cells and other photonic applications to enhance the efficiency of such devices. The invention is not limited to the embodiments, examples, etc. disclosed above. It is appreciated that changes, modifications, etc. can be made by one skilled in the art and still fall within the scope of the invention. As such, the scope of the invention is defined by the claims and all equivalents thereof.

We claim:

1. A band gap material comprising:
an alloy of cadmium, tellurium and magnesium, the alloy doped with oxygen wherein the alloy includes an intermediate band positioned between conduction and valance bands of the alloy wherein the alloy has the formula: Cd₁₋ₓMgₓTeO_{y} wherein 0.1≦x≦0.75 and y≦0.1.

2. The band gap material of claim 1 wherein the alloy has a band gap of from 2.5 to 1.6 eV.

3. The band gap material of claim 1 wherein the alloy has the formula: Mg_{0.25}Cd_{0.75}TeO.

4. The band gap material of claim 3 wherein the alloy has a band gap of 1.9 eV between conduction and valance bands of the material.

5. The band gap material of claim 1 further including a GaAs substrate.

6. The band gap material of claim 1 further including a buffer layer of ZnTe.

7. The band gap material of claim 6 wherein the ZnTe buffer layer has a thickness of about 100 nm.

8. The band gap material of claim 1 further including a buffer layer of CdTe.

9. The band gap material of claim 8 wherein the CdTe buffer layer has a thickness less than 1 μm.

10. A band gap material comprising:
a GaAs substrate,
a buffer layer of ZnTe applied to the GaAs substrate;
a buffer layer of CdTe applied to the buffer layer of ZnTe;
an alloy applied to the buffer layer of CdTe, the alloy being of cadmium, tellurium and magnesium, the alloy doped with oxygen wherein the alloy includes an intermediate band positioned between conduction and valance bands of the alloy wherein the alloy has the formula: Cd₁₋ₓMgₓTeO_{y} wherein 0.1≦x≦0.75 and y≦0.1.

11. The band gap material of claim 10 wherein the alloy has a band gap of from 2.5 to 1.6 eV.

12. The band gap material of claim 10 wherein the alloy has the formula: Mg_{0.25}Cd_{0.75}TeO.

13. The band gap material of claim 12 wherein the alloy has a band gap of 1.9 eV between conduction and valance bands of the material.

14. The band gap material of claim 10 wherein the ZnTe buffer layer has a thickness of about 100 nm.

15. The band gap material of claim 10 wherein the CdTe buffer layer has a thickness less than 1 μm.
